(19) United States
(12) Patent Application Publication
(10) Pub. No.: US 2012/0056238 A1
(43) Pub. Date: Mar. 8, 2012

(54) BIDIRECTIONAL SILICON-CONTROLLED RECTIFIER

(76) Inventors: Wen-Yi CHEN, (US); Ryan Hsin-Chin JIANG, (US); Ming-Dou KER, (US)

(21) Appl. No.: 13/296,506

(22) Filed: Nov. 15, 2011

Related U.S. Application Data
(62) Division of application No. 12/149,287, filed on Apr. 30, 2008.

(51) Int. Cl. H01L 29/747

(52) U.S. Cl. 257/119; 257/E29.215

(57) ABSTRACT

A bidirectional silicon-controlled rectifier, wherein the conventional field oxide layer, which separates an anode structure from a cathode structure, is replaced by a field oxide layer having floating gates, a virtual gate or a virtual active region. Thus, the present invention can reduce or escape from the bird's beak effect of a field oxide layer, which results in crystalline defects, a concentrated current and a higher magnetic field and then causes abnormal operation of a rectifier. Thereby, the present invention can also reduce signal loss.

### CROSS REFERENCE TO RELATED APPLICATIONS

This application is a Divisional of co-pending application Ser. No. 12/149,287, filed on Apr. 30, 2008, for which priority is claimed under 35 U.S.C. §120; the entire contents of which are hereby incorporated by reference.

### BACKGROUND OF THE INVENTION

1. Field of the Invention

The present invention relates to a bidirectional silicon-controlled rectifier, particularly to a bidirectional silicon-controlled rectifier having a novel isolation structure.

2. Description of the Related Art

With the advance of semiconductor technology, the dimensions of MOS (Metal Oxide Semiconductor) elements have been reduced to a submicron or even deep-submicron scale. The submicron or deep-submicron technology uses so thin a gate oxide layer that only a few volts higher voltage is enough to cause damage. In common conditions, the voltage of electrostatic charge may reach thousands or even several ten thousands of volts, which will damage integrated circuits (IC). Therefore, once having accumulated to a given amount, electrostatic charge should be released. The silicon-controlled rectifier, which has a low turn-on resistance, low capacitance, low power consumption and high-power current conduction capability, is exactly an effective ESD (Electro-Static Discharge) protection element for IC. Currently, the bidirectional silicon-controlled rectifier (SCR) has become the mainstream in the market of the ESD protection circuits for I/O ports subject to both positive and negative voltage signals.

The bidirectional silicon-controlled rectifier needs an appropriate isolation structure to separate the anode structure from the cathode structure. The most common isolation structure is the field oxide layer (LOCOS, local oxide of silicon). However, the field oxide layer usually has a serious drawback—the so-called bird's beak effect, which causes a higher stress and then results in more defects and dislocations. The bird's beak effect also causes a higher magnetic field, which results in a greater concentrated current in electro-static discharge (ESD).

U.S. Pat. No. 6,258,634 and No. 6,365,924 both disclosed symmetric bidirectional silicon-controlled rectifiers. However, in the LOCOS process thereof, lateral silicon oxidation under silicon nitride brings about the bird's beak effect, which greatly influences the reliability of the silicon-controlled rectifiers at a high current or under a great amount of electro-static charge. A U.S. Pat. No. 7,145,187 disclosed a symmetric and asymmetric DSCR having a special silicon-controlled rectifier structure. However, it is hard to mass fabricate and lacks utility. A U.S. Pat. No. 7,034,363 disclosed a bidirectional ESD protection device. However, it has bird's beak structures and thus has poor ESD resistance. A U.S. Pat. No. 6,960,792 disclosed an annular-layout symmetric bidirectional silicon-controlled rectifier, but it still cannot escape from the bird's beak effect of LOCOS. A U.S. Pat. No. 5,072,273 disclosed a low triggering voltage silicon-controlled rectifier. However, it can only operate unidirectionally. A US patent No. 2006/0097293 accentuates its immunity to the bird's beak effect, but it essentially applies to MOS structures. A U.S. Pat. No. 6,501,630 is a bidirectional ESD protection device, wherein the first and third P-type regions are formed of a semiconductor substrate and need resistors to operate. However, such a structure not only occupies a large area but also is very sensitive to substrate noise, which results in a serious latch-up problem.

Accordingly, the present invention proposes a novel bidirectional silicon-controlled rectifier to overcome the abovementioned problems.

### SUMMARY OF THE INVENTION

The primary objective of the present invention is to provide a bidirectional silicon-controlled rectifier, which has a field oxide layer with floating gates used to separate the anode structure from the cathode structure, wherein the floating gates can constrain the extension of the bird's beaks at two sides of the field oxide layer and prevent from the structural defects and concentrated current induced by the bird's beak effect.

Another objective of the present invention is to provide a bidirectional silicon-controlled rectifier, which has a virtual gate or virtual active region arranged in between the anode structure and cathode structure to replace the original isolation structure of a field oxide layer and to prevent from the structural defects and concentrated current induced by the isolation structure of a field oxide layer.

Still another objective of the present invention is to provide a bidirectional silicon-controlled rectifier, which provides forward-voltage and backward-voltage ESD protections.

Further another objective of the present invention is to provide a bidirectional silicon-controlled rectifier, which has a smaller leakage current and a lower parasitic capacitance and thus can effectively avoid signal loss.

To achieve the abovementioned objectives, the present invention proposes a bidirectional silicon-controlled rectifier, which comprises: a P-type substrate; an N-type epitaxial layer formed on P-type substrate; an anode structure; a cathode structure; a field oxide layer formed over the N-type epitaxial layer and in between the anode structure and the cathode structure; and two floating gates respectively at two sides of the field oxide layer. The anode structure includes: a first P-type doped area formed inside the N-type epitaxial layer; and a first semiconductor area and a second semiconductor area, wherein the first and second semiconductor areas have opposite conduction types, and wherein the first and second semiconductor areas are both arranged inside the first P-type doped area and both connected to an anode. The cathode structure includes: a second P-type doped area formed inside the N-type epitaxial layer; and a third semiconductor area and a fourth semiconductor area neighboring the first P-type doped area, wherein the third and fourth semiconductor areas have opposite conduction types, and wherein the third and fourth semiconductor areas are both arranged inside the second P-type doped area and both connected to a cathode.

The present invention also proposes a bidirectional silicon-controlled rectifier, which is based on the abovementioned SCR structure, and which centers at the anode structure and has two cathode structures respectively at two sides of the anode structure, wherein the SCR structure is expanded from the abovementioned SCR structure mirror-symmetrically with respect to the vertical central axis of the anode structure, and the cathode structure is duplicated mirror-symmetrically with respect to the vertical central axis of the anode structure.

In another embodiment of the present invention, an N-type buried layer is formed in between the P-type substrate and the N-type epitaxial layer.

In still another embodiment of the present invention, a virtual gate replaces the combination of the abovementioned field oxide layer and floating gates.

In further another embodiment of the present invention, a virtual active region replaces the combination of the abovementioned field oxide layer and floating gates.

Below, the embodiments will be described in detail to make easily understood the objectives, technical contents, characteristics and accomplishments of the present invention.

### BRIEF DESCRIPTION OF THE DRAWINGS

FIG. 1 is a diagram schematically showing a first embodiment of the present invention;

FIG. 2 is a diagram schematically showing a second embodiment of the present invention;

FIG. 3 is a diagram schematically showing a third embodiment of the present invention;

FIG. 4 is a diagram schematically showing a fourth embodiment of the present invention;

FIG. 5 is a diagram schematically showing a fifth embodiment of the present invention; and

FIG. 6 is a diagram schematically showing a sixth embodiment of the present invention.

### DETAILED DESCRIPTION OF THE INVENTION

The present invention proposes bidirectional silicon-controlled rectifiers (SCR). Below, a bidirectional SCR, which has one anode structure and only one cathode structure, is to be introduced as the fundamental architecture of the present invention.

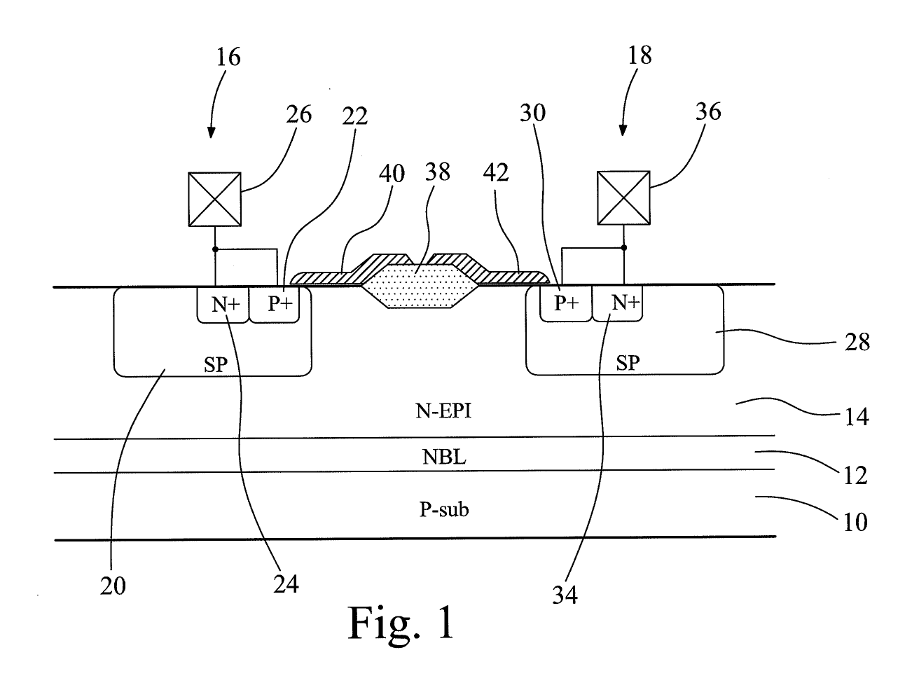

Refer to FIG. 1 a diagram schematically showing a first embodiment of the present invention. In the first embodiment of the present invention, the SCR structure comprises: a P-type substrate 10 having an N-type buried layer 12 formed thereon; an N-type epitaxial layer 14 formed on the N-type buried layer 12; an anode structure 16 and a cathode structure 18, which are all formed inside the N-type epitaxial layer 14, wherein the cathode structure 18 is arranged at the right side of the anode structure 16.

The anode structure 16 has a P-type doped region 20. The P-type doped region 20 has a P+ semiconductor area 22 and an N+ semiconductor area 24. The P+ semiconductor area 22 neighbors the cathode structure 18. The P+ semiconductor area 22 and N+ semiconductor area 24 are both connected to an anode 26.

The cathode structure 18 has a P-type doped region 28. The P-type doped region 28 has a P+ semiconductor area 30 and an N+ semiconductor area 34. The P+ semiconductor area 30 neighbors the anode structure 16. The P+ semiconductor area 30 and N+ semiconductor area 34 are both connected to a cathode 36.

A field oxide layer 38 is formed in between the anode structure 16 and the cathode structure 18. Two floating gates 40 and 42 are respectively formed at two sides of the field oxide layer 38. The floating gate 40 covers a portion of each of the field oxide layer 38, N-type epitaxial layer 14, P-type doped region 20 and P+ semiconductor area 22. The floating gate 42 covers a portion of each of the field oxide layer 38, N-type epitaxial layer 14, P-type doped region 28 and P+ semiconductor area 30.

In this embodiment, the patterns of the floating gates and field oxide layer are formed on the photomask and then transferred onto the silicon-controlled rectifier to obtain the structure shown in FIG. 1. Such a structure—a field oxide layer having floating gates—can limit the extension of two sides of the field oxide layer and thus can prevent two sides of the field oxide layer (bird's beaks) from extending into the anode and cathode edges and degrading ESD robustness of the bidirectional SCR.

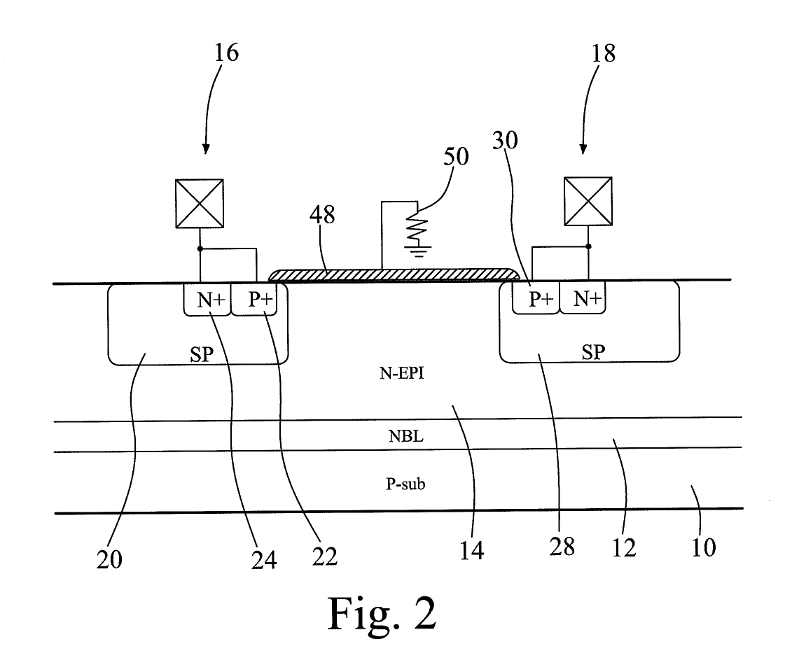

Refer to FIG. 2 a diagram schematically showing a second embodiment of the present invention. In this embodiment, a virtual gate 48 replaces the combination of the field oxide layer 38 and the floating gates 40 and 42 in FIG. 1. The virtual gate 48 covers a portion of each of the P+ semiconductor area 22, P-type doped region 20, N-type epitaxial layer 14, P-type doped region 28 and P+ semiconductor area 30. The virtual gate 48 is grounded via a resistor 50. During ESD events, voltage on the virtual gate 48 is coupled high parasitic capacitance in IC structures, which induces channel current to help turn-on the SCR device. In this embodiment, the pattern of the virtual gate structure is formed on a photomask and arranged in between the patterns of the anode structure and the cathode structure. The virtual-gate isolation structure can separate the anode structure from the cathode structure. Therefore, this embodiment is free of a field oxide layer and thus free of the bird's beak effect.

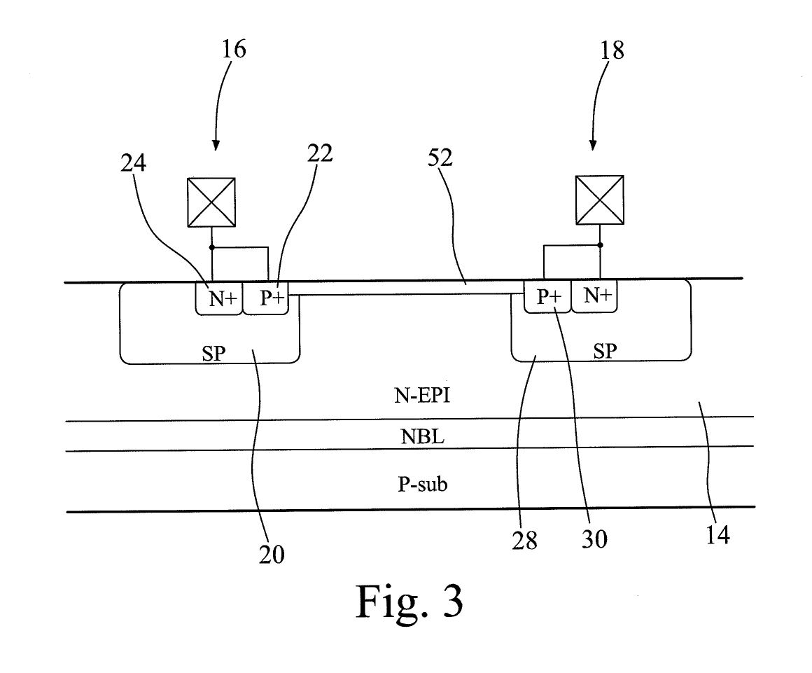

Refer to FIG. 3 a diagram schematically showing a third embodiment of the present invention. In this embodiment, a virtual active region 52 replaces the combination of the field oxide layer 38 and the floating gates 40 and 42 in FIG. 1. The virtual active region 52 is arranged in between the P+ semiconductor area 22 and the P+ semiconductor area 30 and covers a portion of each of the P-type doped region 20, N-type epitaxial layer 14 and P-type doped region 28. Similarly to the embodiment shown in FIG. 2, the virtual active region 52 is also used to separate the anode structure from the cathode structure so that this embodiment can be free of a field oxide layer. Thus, this embodiment is also free of the bird's beak effect.

Next is to be introduced a bidirectional SCR, which centers at an anode structure and has symmetric cathode structures respectively at two sides of the anode structure to reduce the area of the entire SCR architecture.

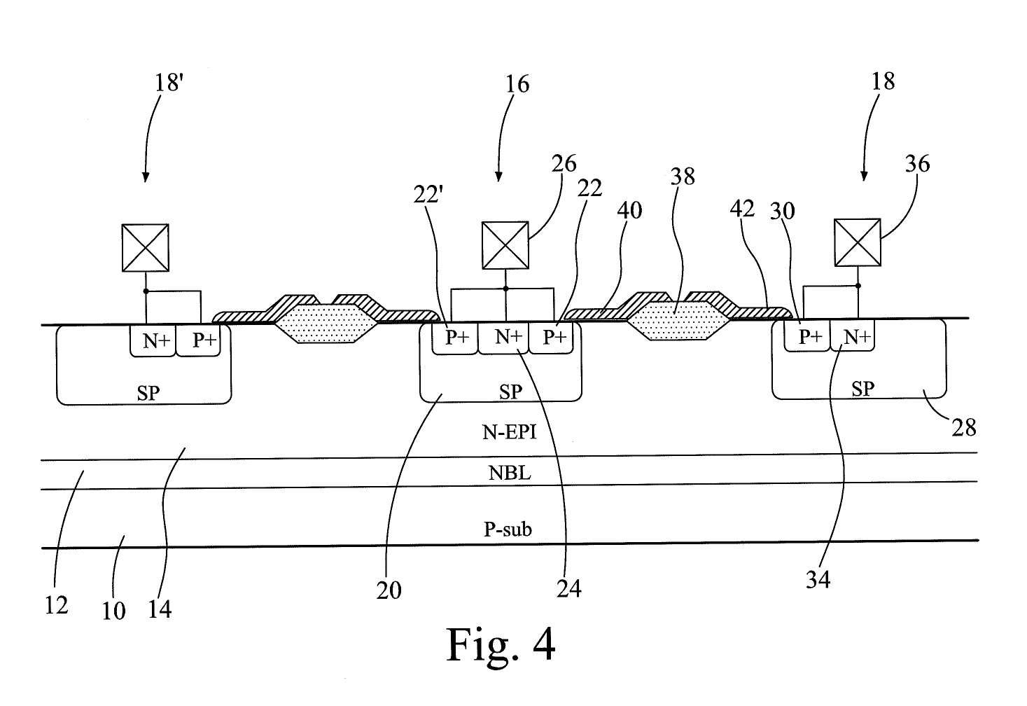

Refer to FIG. 4 a diagram schematically showing a fourth embodiment of the present invention. The bidirectional silicon-controlled rectifier of the present invention comprises: a P-type substrate 10 having an N-type buried layer 12 formed thereon; an N-type epitaxial layer 14 formed on the N-type buried layer 12; an anode structure 16 and two cathode structures 18 and 18′, which are all formed inside the N-type epitaxial layer 14, wherein the two cathode structures 18 and 18′ are identical in structure and respectively arranged at two sides of the anode structure 16.

In the fourth embodiment, the SCR structure in FIG. 4 is expanded from the SCR structure in FIG. 1 mirror-symmetrically with respect to the vertical central axis of the anode structure 16, wherein the cathode structure 18′ is duplicated from the cathode structure 18 in FIG. 1 mirror-symmetrically with respect to the vertical central axis of the anode structure 16.

The anode structure 16 has a P-type doped region 20. The P-type doped region 20 has two P+ semiconductor areas 22 and 22′ and an N+ semiconductor area 24, wherein the N+ semiconductor area 24 is interposed between two P+ semiconductor areas 22 and 22′, and the two P+ semiconductor areas 22 and 22′ and N+ semiconductor area 24 are all connected to an anode 26.

Each of the two cathode structures 18 and 18′ has a P-type doped region 28. The P-type doped region 28 has a P+ semiconductor area 30 and an N+ semiconductor area 34, and the P+ semiconductor area 30 and N+ semiconductor area 34 are all connected to a cathode 36.

A field oxide layer 38 is formed in between the anode structure 16 and either of the cathode structures 18 and 18′. Floating gates 40 and 42 are respectively formed at two sides of the field oxide layer 38. The floating gate 40 covers a portion of each of the field oxide layer 38, N-type epitaxial layer 14, P-type doped region 20 and P+ semiconductor area 22. The floating gate 42 covers a portion of each of the field oxide layer 38, N-type epitaxial layer 14, P-type doped region 28 and P+ semiconductor area 30.

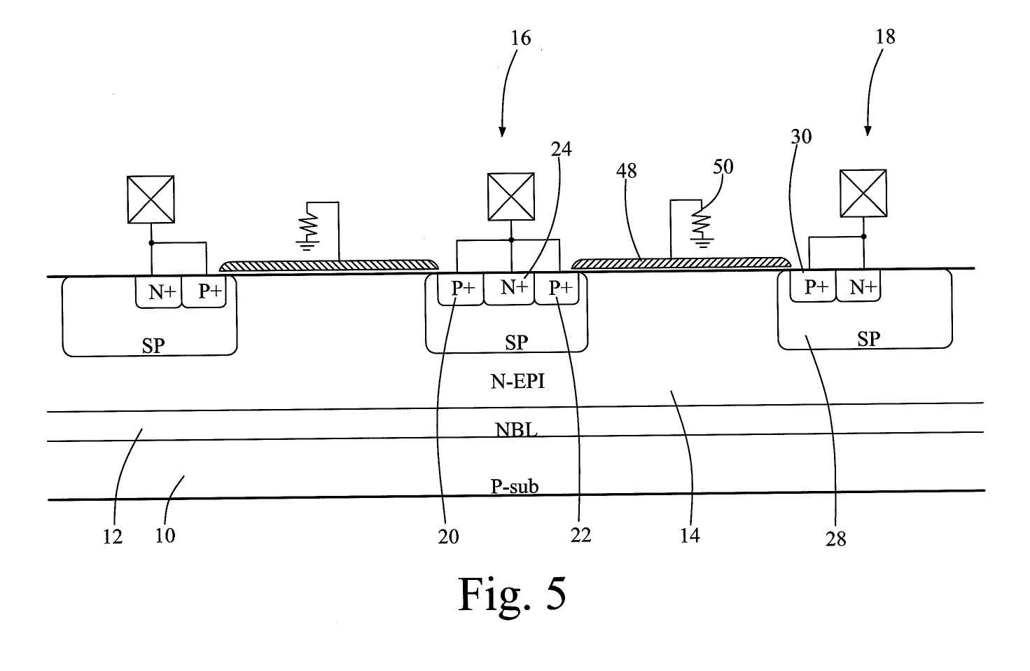

Refer to FIG. 5 a diagram schematically showing a fifth embodiment of the present invention. In this embodiment, a virtual gate 48 replaces the combination of the field oxide layer 38 and the floating gates 40 and 42 in FIG. 4, and the virtual gate 48 covers a portion of each of the P+ semiconductor area 22, P-type doped region 20, N-type epitaxial layer 14, P-type doped region 28 and P+ semiconductor area 30. The virtual gate 48 is grounded via a resistor 50.

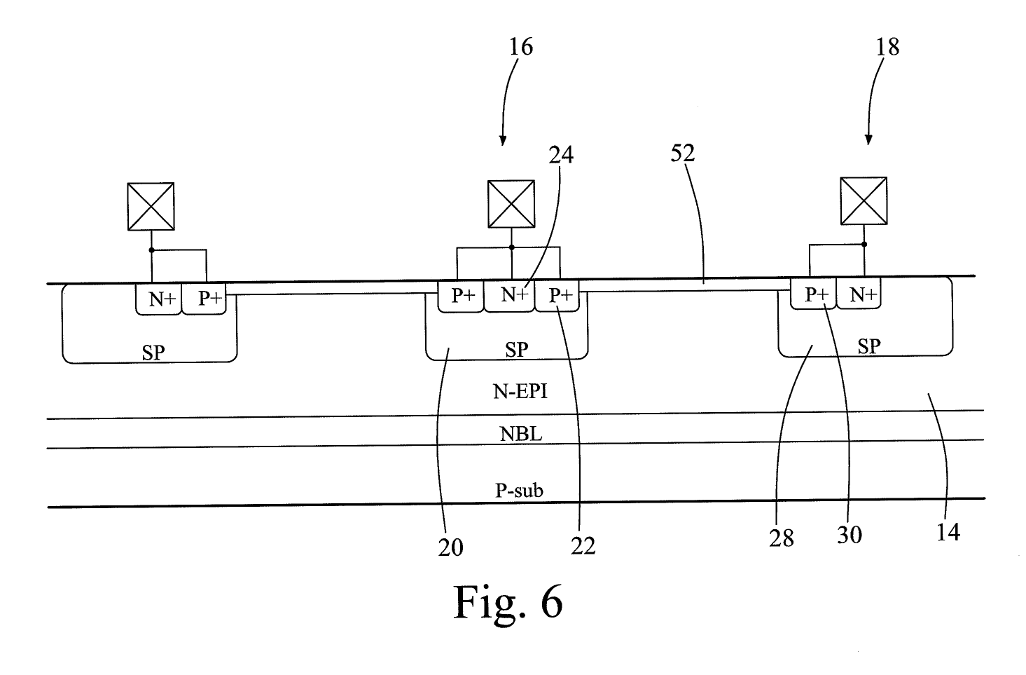

Refer to FIG. 6 a diagram schematically showing a sixth embodiment of the present invention. In this embodiment, a virtual active region 52 replaces the combination of the field oxide layer 38 and the floating gates 40 and 42 in FIG. 4. The virtual active region 52 is arranged in between the P+ semiconductor area 22 and the P+ semiconductor area 30 and covers a portion of each of the P-type doped region 20, N-type epitaxial layer 14 and P-type doped region 28. Similarly the embodiment shown in FIG. 5, the virtual active region 52 is also used to separate the anode structure from the cathode structure so that this embodiment can be free of a field oxide layer. Thus, this embodiment is also free of the bird's beak effect.

In conclusion, the present invention utilizes a photomask to pattern the floating gates and the field oxide layer, and the floating gates constrain the extension of the bird's beaks to prevent the operation of the anode and cathode structures from being influenced by the crystalline defects resulting from the bird's beak effect. Alternatively, the present invention utilizes a photomask to pattern a virtual gate or a virtual active region, which replaces the combination of the field oxide layer and the floating gates to function as an isolation element for separating the anode structure from the cathode structure. Thereby, the silicon-control rectifier structure can avoid the increase of the dislocations and structural defects caused by the bird's beak effect. Further, the present invention can escape from the problems caused by a higher magnetic field and concentrated current. Furthermore, because of smaller leakage current and lower parasitic capacitance, the present invention can effective reduce signal loss.

Those described above are only the preferred embodiments to exemplify the present invention but not to limit the scope of the present invention. Any equivalent modification or variation according to the spirit and characteristics disclosed in the present invention is to be also included within the scope of the present invention.

What is claimed is:

1. A bidirectional silicon-controlled rectifier comprising:
a P-type substrate;
an N-type epitaxial layer formed on said P-type substrate;
an anode structure including:
a first P-type doped area formed inside said N-type epitaxial layer; and
a first semiconductor area and a second semiconductor area, wherein said first and second semiconductor area have opposite conduction types, are both arranged inside said first P-type doped area and are both connected to an anode;
a cathode structure including:
a second P-type doped area formed inside said N-type epitaxial layer; and
a third semiconductor area and a fourth semiconductor area neighboring said first P-type doped area, wherein said third and fourth semiconductor areas have opposite conduction types, are both arranged inside said second P-type doped area and are both connected to a cathode;
a field oxide layer formed over said N-type epitaxial layer and in between said anode structure and said cathode structure, wherein said second semiconductor area and said fourth semiconductor area neighbor said field oxide layer and are of an identical conduction type; and
two floating gates respectively at two sides of said field oxide layer.

2. A bidirectional silicon-controlled rectifier according to claim 1, wherein an N-type buried layer is formed in between said P-type substrate and said N-type epitaxial layer.

3. A bidirectional silicon-controlled rectifier according to claim 1, which is expanded mirror-symmetrically with respect to a vertical central axis of said anode structure, and which centers at said anode structure and has two said cathode structures respectively at two sides of said anode structure.

4. A bidirectional silicon-controlled rectifier according to claim 3, wherein said floating gates respectively cover a portion of each of said first P-type doped area and said second semiconductor area and a portion of each of said second P-type doped area and said fourth semiconductor area.

5. A bidirectional silicon-controlled rectifier according to claim 3, wherein an N-type buried layer is formed in between said P-type substrate and said N-type epitaxial layer.
